(19) United States
(12) Patent Application Publication
(10) Pub. No.: US 2025/0102901 A1
(43) Pub. Date: Mar. 27, 2025

(54) CONTACTS FOR REDUCING WEAR IN A RETICLE CONTAINER

(71) Applicant: ENTEGRIS, INC., Billerica, MA (US)

(72) Inventors: Huaping Wang, Eden Prairie, MN (US); Russ V. Raschke, Chanhassen, MN (US)

(21) Appl. No.: 18/892,069

(22) Filed: Sep. 20, 2024

Related U.S. Application Data
(60) Provisional application No. 63/539,978, filed on Sep. 22, 2023.

(51) Int. Cl. G03F 1/38; G03F 1/66

(52) U.S. Cl. CPC G03F 1/38; G03F 1/66

(57) ABSTRACT

Reticle contacts for use in a reticle container are provided having further features for wear reduction. The wear reduction features include one or more of a ring-shaped projection or one or more elongate arcing projections from a reticle contact region, one or more reliefs such as ring-shaped trenches provided in a reticle contact region, or one or more reliefs provided by having relatively thinner regions of the reticle contact region.

### FIELD

This disclosure is directed to reticle contacts for use in reticle containers, and reticle containers such as reticle pods including such reticle contacts.

### BACKGROUND

Reticles, such as photolithography reticles, for example for extreme ultraviolet (EUV) photolithography, can be retained within reticle containers by way of contacts. Wear can occur at the interface between the contacts and the reticle. When wear affects the contacts, particulate material can be generated, which can contaminate or damage the reticle. When wear affects the reticle, at least portions of a coating of the reticle can be damaged.

### SUMMARY

This disclosure is directed to reticle contacts for use in reticle containers, and reticle containers such as reticle pods including such reticle contacts.

By reducing wear at an interface between a reticle container and the claimed reticle, the generation of particulate contamination and/or damage to a surface of the reticle can be suppressed.

In an embodiment, an article includes a reticle contact for a reticle pod. The reticle contact includes a reticle contact body configured to be received in a cover of the reticle pod or a baseplate of the reticle pod and a reticle contact region at a distal end of the reticle contact body. The reticle contact region includes a wear reduction feature.

In an embodiment, the wear reduction feature includes one or more elongate arcing projections. In an embodiment, the one or more elongate arcing projections surround a reticle contact region. In an embodiment, the one or more elongate arcing projections include one or more rings, each of said one or more rings surrounding a center of the reticle contact region. In an embodiment, a maximum height of the reticle contact region is provided on at least one of the one or more arcing projections, and wherein transitions from side walls of the one or more arcing projections to a reticle contact surface of the one or more arcing projections are radiused over a distance of 0.3 millimeters (mm) or less.

In an embodiment, the wear reduction feature includes at least one relief provided in the reticle contact region. In an embodiment, the relief has a depth of at least 0.1 millimeters (mm). In an embodiment, the at least one relief includes a ring-shaped trench. In an embodiment, the ring-shaped trench has an inner diameter in a range from 0.1 millimeters (mm) to 3.0 mm. In an embodiment, transitions from side walls of the ring-shaped trench to a reticle contact surface of the reticle contact region are radiused over a distance of 0.3 millimeters (mm) or less.

In an embodiment, the wear reduction feature includes a first region of the reticle contact region where a thickness of the reticle contact is relatively less than a thickness of the reticle contact at a second region of the reticle contact surface. In an embodiment, the first region of the reticle contact overlaps with a center of the reticle contact region.

In an embodiment, the wear reduction feature includes a plurality of projections from the reticle contact region, wherein at least one of the plurality of projections has an elongate cross-sectional shape.

In an embodiment, the reticle contact surface has a radius R1, a transition between the side wall of the wear reducing feature to the reticle contact surface has a radius R2, and R2 is less than 80% of R1.

In an embodiment, the article further includes a flexible mounting configured to allow the reticle contact to move relative the cover of the reticle pod or the baseplate of the reticle pod when the flexible mounting is deformed.

In an embodiment, a reticle pod includes a cover, a baseplate, and at least one of the article as described herein. In an embodiment, the reticle pod further includes a pod dome and a pod door.

In an embodiment, a reticle pod includes a cover, a baseplate, and a plurality of the articles as described herein. In an embodiment, some of the plurality of the articles are provided on the cover and some of the plurality of the articles are provided on the baseplate. In an embodiment, the reticle pod further includes a pod dome and a pod door.

### DRAWINGS

FIG. 1 shows a reticle container according to an embodiment.

FIG. 2A shows a sectional view of a reticle contact according to an embodiment.

FIG. 2B shows a top view of the reticle contact of FIG. 2A.

FIG. 2C shows a close-up sectional view of the reticle contact of FIG. 2A.

FIG. 3A shows a sectional view of a reticle contact according to an embodiment.

FIG. 3B shows a top view of the reticle contact of FIG. 3A.

FIG. 3C shows a sectional view at a reticle contact surface of the reticle contact of FIG. 3A.

FIG. 4 shows a sectional view at a reticle contact surface of a reticle contact according to an embodiment.

FIG. 5 shows a sectional view of a reticle contact according to an embodiment.

FIG. 6A shows a top view of a reticle contact according to an embodiment.

FIG. 6B shows a top view of a reticle contact according to an embodiment.

### DETAILED DESCRIPTION

This disclosure is directed to reticle contacts for use in reticle containers, and reticle containers such as reticle pods including such reticle contacts.

As used herein, “reticle contact region” is a region of a reticle contact configured to face a reticle when the reticle is placed in a reticle container including the reticle contact. As used herein, at least some of the reticle contact region may contact the reticle when the reticle container is closed with the reticle contained within. In some embodiments, not all of the reticle contact region actually contacts the reticle when the reticle is contained within a reticle pod including the reticle contact.

As used herein, “reticle contact surface” is a surface configured or capable to make contact with a reticle. The reticle contact surface can be a portion of the reticle contact region or on a portion of a wear reducing feature extending from said reticle contact region. The reticle contact surface can be domed or radiused, or generally flat, where “generally flat” is defined as being planar to the extent possible for the materials and manufacturing methods used to form such a reticle contact surface. In embodiments, the reticle contact surface can include multiple different arcs or radiuses across the reticle contact surface when the reticle contact surface is seen in a sectional view.

As used herein, “generally perpendicular” means transverse, substantially transverse, or a relative angular orientation of 60° to 120°.

As used herein, “generally rectangular” refers to a rectangular shape that may have rounded corners and/or rounded edges.

As used herein, “sharp corner” refers to a discontinuous transition.

As used herein, “wear reduction feature” refers to a feature providing a reticle contact surface and/or provided in a reticle contact surface, the wear reduction feature configured to reduce the incidence of wear caused by contact between a reticle contact surface and a reticle. The wear reduction feature can be, for example, any of the embodiments provided herein.

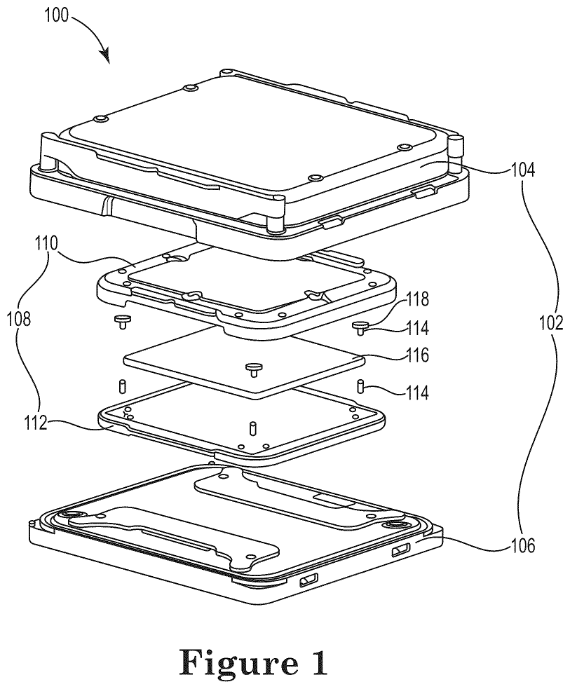

FIG. 1 shows a reticle container according to an embodiment. Reticle pod 100 includes an outer pod 102 including pod dome 104 and pod door 106. Reticle pod 100 further includes inner pod 108, which includes cover 110 and baseplate 112. Reticle contacts 114 can be provided in one or both of the cover 110 and baseplate 112. Reticle 116 can be contained within the reticle pod 100. At least some of reticle contacts 114 include a flexible mounting 118.

Reticle pod 100 is configured to accommodate a reticle 116, for example for transportation or storage of that reticle 116. Reticle 116 can be any suitable reticle that can be contained within reticle pod 100, such as a photolithography mask. In an embodiment, reticle 116 is a reticle for extreme ultraviolet (EUV) photolithography. The reticle 116 includes surfaces that are contacted by the reticle contacts 114 when reticle 116 is contained within the inner pod 108 of reticle pod 100.

Outer pod 102 forms an exterior of reticle pod 100 when reticle pod 100 is fully assembled. Outer pod 102 is configured to form an internal space capable of accommodating inner pod 108. Outer pod 102 can be formed of pod dome 104 and pod door 106. Pod dome 104 and pod door 106 can be configured to be joined to one another, for example using a latching mechanism (not shown). The pod dome 104 and pod door 106 can be configured such that the inner pod 108 is retained within the internal space defined by the pod dome 104 and pod door 106.

Inner pod 108 is a pod configured to accommodate the reticle 116. Inner pod 108 includes the cover 110 and the baseplate 112. The inner pod 108 is configured such that it can fit within the internal space of outer pod 102.

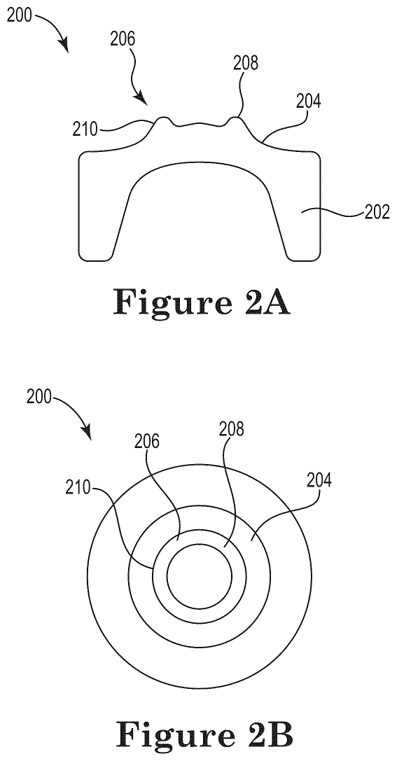

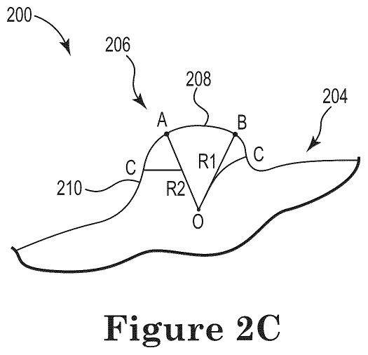

Reticle contacts 114 are each configured to be attached to one of cover 110 or baseplate 112. The reticle contacts 114 are configured to contact reticle 116 so as to retain the position of the reticle 116 within the inner pod 108. The reticle contacts 114 can be made of any suitable material based on cleanliness, compatibility, resilience, and the like. A non-limiting example of a suitable material for the reticle contacts 114 is a polyether ether ketone (PEEK) material. Examples of reticle contacts 114 are shown in further detail in FIGS. 2A-4 and described below.

In an embodiment, at least some of reticle contacts 114 can be supported by a flexible mounting 118, such as a spring at the interface between the reticle contact 114 and cover 110 or baseplate 112. In an embodiment, the reticle contacts 114 attached by flexible mounting 118 can be provided on the cover 110. In an embodiment, the reticle contacts 114 attached by flexible mounting 118 can include a spring attached to the reticle contact 114. The flexible mounting 118 can allow the associated reticle contact 114 to be vertically movable, for example as with the vertically movable reticle posts of U.S. Pat. No. 8,613,359, which is herein incorporated by reference in its entirety.

FIG. 2A shows a sectional view of a reticle contact according to an embodiment. Reticle contact 200 includes reticle contact body 202 and reticle contact region 204 including one or more wear reducing features 206.

Reticle contact 200 is configured to be inserted into a cover or baseplate of an inner pod of a reticle pod, such as cover 110 or baseplate 112 of an inner pod 108 as discussed above and shown in FIG. 1. Reticle contact 200 can be formed of any suitable material, such as PEEK.

Reticle contact 200 includes reticle contact body 202. Reticle contact body 202 is configured to be at least partially received in the cover or baseplate of the reticle pod, such as in a channel, depression, opening, or the like, such that the reticle contact 200 is retained to the cover or baseplate. Reticle contact body 202 can be configured such that the reticle contact region 204 is provided at a desired position, such as a desired height, a desired position relative to the reticle, or the like.

Reticle contact region 204 is a portion of the reticle contact 200 configured to face the reticle when the reticle contact 200 is installed in a cover or baseplate and a reticle is contained within the cover or baseplate. At least some of the reticle contact region 204 may contact the reticle when the reticle container is closed with the reticle contained within. In some embodiments, not all of the reticle contact region 204 actually contacts the reticle when the reticle is contained within a reticle pod including the reticle contact 200.

Wear reducing features 206 are provided on reticle contact region 204. In reticle contact 200, the wear reducing feature 206 includes one or more elongate arcing projections provided in the reticle contact region. The wear reducing features 206 of reticle contact 200 can be the reticle contact surface, providing contact between the reticle and reticle contact 200. In an embodiment, only the wear reducing features 206 of reticle contact 200 are configured to contact the reticle. In the embodiment shown in FIGS. 2A and 2B, the wear reducing feature 206 is a ring-shaped projection extending outwards from the surface of reticle contact region 204. The ring-shaped projection can surround a center of the reticle contact region 204. In an embodiment, a plurality of ring-shaped projections can be provided as the wear-reducing features 206. In an embodiment, the ring-shaped projections of such a plurality can be concentric with one another. In an embodiment, one or more of the ring-shaped projections are concentric with the center of the reticle contact region 204. In an embodiment, instead of a ring-shaped projection, the wear reducing feature 206 can include one or more projections from the reticle contact region that are elongate and arcing so as to define a ring with one or more gaps formed between the elongate arcing projections forming said ring. The elongate arcing projections define the ring surrounding a center of the reticle contact region 204. In an embodiment, at least some of the elongate arcing projections can be radially inward or outward of other elongate arcing projections or a ring-shaped projection. In an embodiment, the side walls of the elongate arcing projections and/or rings can be generally perpendicular to a reticle contact surface of the wear reducing feature 206. Transitions from a reticle contact surface 208 of the wear reducing feature 206 to a side wall 210 of the wear reducing feature 206 can be abrupt or minimally radiused. As used herein, “minimally radiused” means being radiused over as short a distance as possible when accounting for the material used for the reticle contact 200 and/or the method by which reticle contact 200 is formed, for example by injection molding of the PEEK material. In an embodiment, the radiusing can be over a distance of 0.3 mm or less. In an embodiment, the radiusing can be over a distance of 0.1 mm or less. In an embodiment, the radiusing can be over a distance of 0.05 mm or less. In an embodiment, the transition from the reticle contact surface 208 to the side wall 210 of the wear reducing feature 206 can be a sharp corner. In an embodiment, the transition from the reticle contact surface to the side wall of the wear reducing feature 206 can be radiused. In an embodiment, the transition from the reticle contact surface 208 to the side wall 210 can have radiusing over as small distance as possible for the material and manufacturing method used to form said reticle contact 200, such as molding of PEEK.

FIG. 2B shows a top view of reticle contact 200. In the top view of FIG. 2B, the ring shape of the wear reducing feature 206 can be seen, with the wear reducing feature 206 surrounding a center of the reticle contact region 204.

FIG. 2C shows a close-up sectional view of reticle contact 200 at wear reducing feature 206. Reticle contact surface 208 has outermost point A and inmost point B, where the reticle contact surface 208 transitions to the side walls 210 of the wear reducing feature 206. The outermost point A on the outer perimeter of reticle contact surface 208 and the corresponding inmost point B on the inner perimeter of the reticle contact surface 208 define the radius of the reticle contact surface R1. The transition from outermost point A to the corresponding side wall 210 is radiused, with the radius of the transition being R2. In an embodiment, R2 is less than 80% of R1. In an embodiment, R2 is less than 70% of R1. In an embodiment, R2 is less than 60% of the R1. In an embodiment, R2 is less than 50% of R1. In an embodiment, R2 is less than 40% of R1. In an embodiment, the radius R1 can vary across the reticle contact surface 208, when reticle contact surface 208 is viewed in a sectional view. In an embodiment, the radius R2 can vary across the transition from reticle contact surface 208 to side wall 210 when the wear reducing feature 206 is viewed in section view.

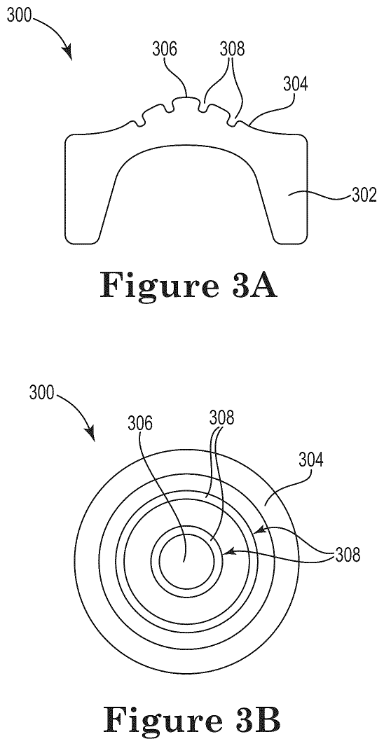

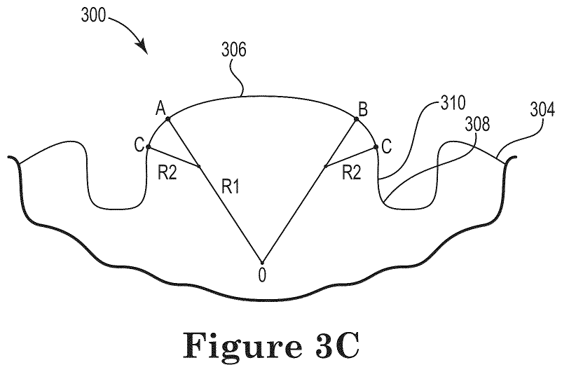

FIG. 3A shows a sectional view of a reticle according to an embodiment. Reticle contact 300 includes reticle contact body 302 and reticle contact region 304 including one or more reticle contact surfaces 306. Reticle contact region 304 further includes one or more wear reducing features 308.

Reticle contact 300 is configured to be inserted into a cover or baseplate of an inner pod of a reticle pod, such as cover 110 or baseplate 112 of an inner pod 108 as discussed above and shown in FIG. 1. Reticle contact 300 can be formed of any suitable material, such as PEEK.

Reticle contact 300 includes body 302. Body 302 is configured to be at least partially received in the cover or baseplate of the reticle pod, such as in a channel, depression, opening, or the like, such that the reticle contact 300 is retained to the cover or baseplate. Body 302 can be configured such that the reticle contact region 304 is provided at a desired position, such as a desired height, a desired position relative to the reticle, or the like.

Reticle contact region 304 is a portion of the reticle contact 300 configured to face the reticle when the reticle contact 300 is installed in a cover or baseplate and a reticle is contained within the cover or baseplate. At least some of the reticle contact region 304 may contact the reticle when the reticle container is closed with the reticle contained within. In some embodiments, not all of the reticle contact region 304 actually contacts the reticle when the reticle is contained within a reticle pod including the reticle contact 300.

Reticle contact surface 306 is a portion of the reticle contact 300 in the reticle contact region 304 that is configured or capable to make contact with the reticle when the reticle is retained within the reticle container including reticle contact 300. In an embodiment, reticle contact surface 306 can be a portion of a domed surface included in the reticle contact region 304. In an embodiment, the reticle contact surface can be a projection from the reticle contact region 304.

Wear reducing features 308 are provided on reticle contact region 304. In the embodiment shown in FIGS. 3A and 3B, the wear reducing feature 308 includes one or more reliefs formed in the reticle contact region 304. In an embodiment, the reliefs are trenches formed in the reticle contact region 304. The trenches can have any suitable width and depth for the size of the reticle contact region, material thickness of the reticle contact 300, and the like. In an embodiment, a depth of the trench is greater than 0.1 millimeters (mm). In an embodiment, a width of the trench can be at or about 0.1 mm. In an embodiment, the reliefs are formed in the reticle contact surface 306. In an embodiment, the reliefs are one or more ring-shaped trenches formed in the reticle contact region 304. In an embodiment, inner diameter(s) of each of the one or more ring-shaped trenches are in a range from 0.1 mm to 3.0 mm. In an embodiment, inner diameter(s) of each of the one or more ring-shaped trenches are in a range from 0.1 mm to 1.0 mm. In embodiments where a plurality of ring-shaped trenches are provided, at least some of the ring-shaped trenches are concentric. In an embodiment, at least one of the ring-shaped trenches are concentric with the reticle contact surface 306. In an embodiment, the trenches can have abrupt drops from the reticle contact surface 306 into the trench, with the transition from reticle contact surface 306 to the side walls 310 of the trench having no or minimal radiusing. As used herein, “minimally radiused” means being radiused over as short a distance as possible when accounting for the material used for the reticle contact 300 and/or the method by which reticle contact 300 is formed, for example by injection molding of the PEEK material. In an embodiment, the radiusing can be over a distance of 0.3 mm or less. In an embodiment, the radiusing can be over a distance of 0.1 mm or less. In an embodiment, the radiusing can be over a distance of 0.05 mm or less. In an embodiment, the side walls 310 of the trench can be generally perpendicular to a surface of the reticle stored within the reticle pod including reticle contact 300. In an embodiment, the radiusing from reticle contact surface 306 to side wall 310 can be over a distance that is approximately 3% or less of a radius of the reticle contact surface 306 surrounded by the trench, when the reticle contact surface is viewed in plan view. In an embodiment, sharp corners can be provided at the transition from the reticle contact surface 306 to the side wall of the trench. The radiusing provided at the transitions can be over a distance shorter than a width of the reticle contact surface 306.

FIG. 3B shows a top view of reticle contact 300. In the top view of FIG. 3B, the ring shape of the trenches that are wear reducing feature 308 can be seen, with two such wear reducing feature 308 surrounding a center of the reticle contact region 304.

FIG. 3C shows a sectional view of reticle contact 300 at the reticle contact surface 306 within reticle contact region 304. The wear reducing feature 308 can be seen, having a side wall 310 generally perpendicular to a plane of a reticle when the reticle is placed on reticle contact surface 306. The transition from the reticle contact surface 306 to the side wall of wear reducing feature 308 is shown as being from A-C and from B-C in FIG. 3C. The radiusing at these transitions can be minimal. In an embodiment, the radiused transition can have a length of 0.3 mm or less. In an embodiment, the radiused transition can have a length of 0.1 mm or less. In an embodiment, the radiused transition can have a length of 0.05 mm or less. In an embodiment, the edges of the trench can be generally perpendicular to a surface of the reticle stored within the reticle pod including reticle contact 300. In an embodiment, the radiused transition can have a length that is approximately 3% or less of a radius of the reticle contact surface 306 surrounded by the trench. In an embodiment, the transition from the reticle contact surface 306 to the side walls 310 of the trench can be rounded or otherwise radiused. In an embodiment, a circle including an arc extending between the edges of the reticle contact surface 306 at a transition to a side wall 310 of the wear reducing feature 308 has a radius R1, a transition between the side wall 310 of the wear reducing feature to the reticle contact surface has a radius R2, and R2 is less than 80% of R1. In this embodiment, the R2 can be 80% or less of the R1. In an embodiment, R2 is less than 70% of R1. In an embodiment, length R2 is less than 60% of the R1. In an embodiment, R2 is less than 50% of R1. In an embodiment, length R2 is less than 40% of the R1. In an embodiment, the reticle contact 300 can have as small an R2 as possible for the material and manufacturing method used to form said reticle contact 300, such as molding of PEEK. In an embodiment, the radius R1 can vary across the reticle contact surface 306, when reticle contact surface 306 is viewed in a sectional view. In an embodiment, the radius R2 can vary across the transition from reticle contact surface 306 to side wall 310 when the wear reducing feature 308 is viewed in section view.

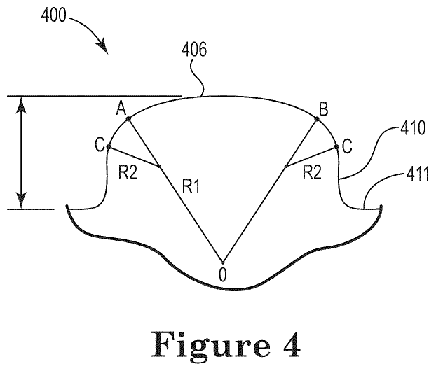

FIG. 4 shows a sectional view at a reticle contact surface of a reticle contact according to an embodiment. In an embodiment, the wear reducing feature is a side wall 410 of the reticle contact region 404. The side wall 410 has generally perpendicular to a plane of a reticle when the reticle is placed on reticle contact surface 406. The transition from the reticle contact surface 406 to the side wall 410 is shown as being from A-C and from B-C in FIG. 4. The radiusing at these transitions can be minimal. In an embodiment, the radiused transition can have a length of 0.3 mm or less. In an embodiment, the radiused transition can have a length of 0.1 mm or less. In an embodiment, the radiused transition can have a length of 0.05 mm or less. In an embodiment, the radiused transition can have a length that is approximately 3% or less of a radius of the reticle contact surface 406. In an embodiment, the transition from the reticle contact surface 406 to the side walls 410 can be rounded or otherwise radiused. In an embodiment, a circle including an arc extending between the edges of the reticle contact surface 406 at a transition to the side wall 410 has a radius R1, a transition between the side wall 410 to the reticle contact surface has a radius R2, and R2 is less than 80% of R1. In this embodiment, the R2 can be 80% or less of the R1. In an embodiment, R2 is less than 70% of R1. In an embodiment, length R2 is less than 60% of the R1. In an embodiment, R2 is less than 50% of R1. In an embodiment, length R2 is less than 40% of the R1. In an embodiment, the reticle contact 400 can have as small an R2 as possible for the material and manufacturing method used to form said reticle contact 400, such as molding of PEEK. In an embodiment, the radius R1 can vary across the reticle contact surface 406, when reticle contact surface 406 is viewed in a sectional view. In an embodiment, the radius R2 can vary across the transition from reticle contact surface 406 to side wall 410 when viewed in section view. In an embodiment a height of the side wall 410 measured between a bottom portion of the side wall 411 and the reticle contact surface 406 is 0.2 mm or greater.

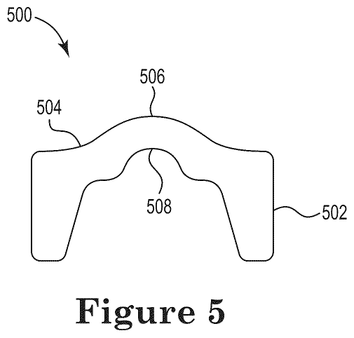

FIG. 5 shows a sectional view of a reticle contact according to an embodiment. Reticle contact 500 includes body 502 and reticle contact region 504 including reticle contact surface 506. Reticle contact region 504 further includes one or more wear reducing features 508.

Reticle contact 500 is configured to be inserted into a cover or baseplate of an inner pod of a reticle pod, such as cover 110 or baseplate 112 of an inner pod 108 as discussed above and shown in FIG. 1. Reticle contact 500 can be formed of any suitable material, such as PEEK.

Reticle contact 500 includes body 502. Body 502 is configured to be at least partially received in the cover or baseplate of the reticle pod, such as in a channel, depression, opening, or the like, such that the reticle contact 500 is retained to the cover or baseplate. Body 502 can be configured such that the reticle contact region 504 is provided at a desired position, such as a desired height, a desired position relative to the reticle, or the like.

Reticle contact region 504 is a portion of the reticle contact 500 configured to face the reticle when the reticle contact 500 is installed in a cover or baseplate and a reticle is contained within the cover or baseplate. At least some of the reticle contact region 504 may contact the reticle when the reticle container is closed with the reticle contained within. In some embodiments, not all of the reticle contact region 504 actually contacts the reticle when the reticle is contained within a reticle pod including the reticle contact 500.

Reticle contact surface 506 is a portion of the reticle contact 500 in the reticle contact region 504 that is configured to make contact with the reticle when the reticle is retained within the reticle container including reticle contact 500. In an embodiment, reticle contact surface 506 can be a portion of a domed surface included in the reticle contact region 504. In an embodiment, the reticle contact surface can be a projection from the reticle contact region 504.

Wear reducing features 508 include one or more reliefs formed in the reticle contact region 504, on a side opposite the reticle contact surface 506. The reliefs can be one or more portions of the reticle contact region 504 having relatively reduced thickness compared to other portions of the reticle contact region 504. In an embodiment, the reliefs can include a portion at a position corresponding to a center of the reticle contact surface 506 where the reticle contact region 504 has the relatively reduced thickness. In an embodiment, a thickness of the reticle contact 500 at the wear-reducing features 508 can be in a range of from 25% to 75% of a thickness of the reticle contact 500 at body 502.

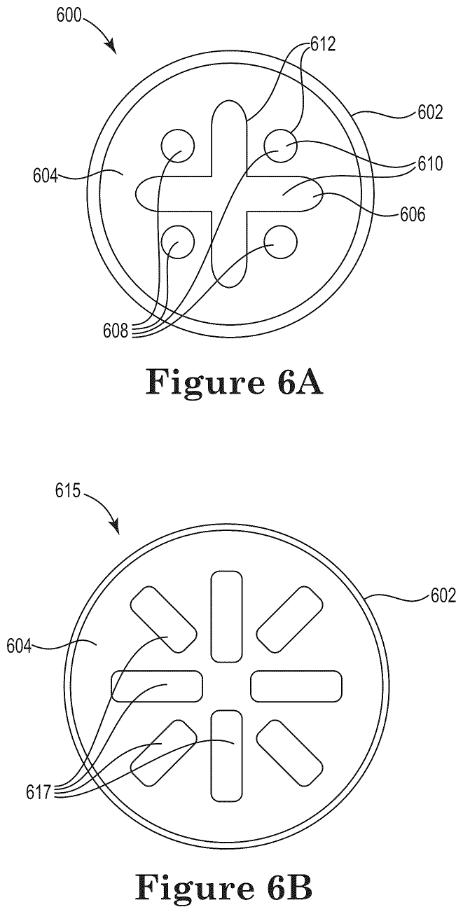

FIG. 6A shows a top view of a reticle contact according to an embodiment. Reticle contact 600 includes body 602, reticle contact region 604, first wear-reducing feature 606 and second wear-reducing feature 608.

Reticle contact 600 includes body 602. Body 602 is configured to be at least partially received in the cover or baseplate of the reticle pod, such as in a channel, depression, opening, or the like, such that the reticle contact 600 is retained to the cover or baseplate. Body 602 can be configured such that the reticle contact region 604 is provided at a desired position, such as a desired height, a desired position relative to the reticle, or the like.

Reticle contact region 604 is a portion of the reticle contact 600 configured to face the reticle when the reticle contact 600 is installed in a cover or baseplate and a reticle is contained within the cover or baseplate. At least some of the reticle contact region 604 may contact the reticle when the reticle container is closed with the reticle contained within. In some embodiments, not all of the reticle contact region 604 actually contacts the reticle when the reticle is contained within a reticle pod including the reticle contact 600.

First wear reducing feature 606 is projection outwards from reticle contact region 604 having a cross-shaped cross-sectional shape, being elongate in two perpendicular directions. The first wear reducing feature 606 can project above reticle contact region 604 such that the first wear reducing feature 606 is in contact with the reticle when a reticle pod including reticle contact 600 is closed with a reticle contained within.

Second wear reducing features 608 can further be provided on reticle contact region 604. The second wear reducing features 608 are projections outwards from the reticle contact region 604. The second wear reducing features 608 can have a circular cross-sectional shape. The second wear-reducing features 608 can each be respectively positioned within one of the quadrants defined by the cross shape of first wear reducing feature 606.

Transitions from a reticle contact surfaces of the wear reducing features 606 and/or 608 to a side wall of those wear reducing features 606 and/or 608 can be a sharp corner or minimally radiused. As used herein, “minimally radiused” means being radiused over as short a distance as possible when accounting for the material used for the reticle contact 600 and/or the method by which reticle contact 600 is formed, for example by injection molding of the PEEK material. In an embodiment, the radiusing can be over a distance of 0.3 mm or less. In an embodiment, the radiusing can be over a distance of 0.1 mm or less. In an embodiment, the radiusing can be over a distance of 0.05 mm or less. In an embodiment, the transitions from the reticle contact surfaces 610 to the side walls 612 of the wear reducing features 606 and/or 608 can be a sharp corner. In an embodiment, the transitions from the reticle contact surfaces 610 to the side walls 612 of the wear reducing features 606 and/or 608 can be radiused. In an embodiment, the radiusing at the transitions from the reticle contact surfaces 610 to the side walls 612 of the wear reducing features 606 and/or 608 can be provided over a distance shorter than a width of the reticle contact surface 610 of the respective wear reducing features 606 and/or 608. In an embodiment, an outermost point A on an outer perimeter of reticle contact surface 610 and the corresponding inmost point B on the inner perimeter of the reticle contact surface 610 define the radius of the reticle contact surface R1. The transition from outermost point A to the corresponding side wall 612 is radiused, with the radius of the transition being R2. In an embodiment, R2 is less than 80% of R1. In an embodiment, R2 is less than 70% of R1. In an embodiment, R2 is less than 60% of the R1. In an embodiment, R2 is less than 50% of R1. In an embodiment, R2 is less than 40% of R1. In an embodiment, the radius R1 can vary across the reticle contact surface(s) 610, when said reticle contact surface(s) 610 are viewed in a sectional view. In an embodiment, the radius R2 can vary across the transition from reticle contact surface(s) 610 to the respective side wall(s) 612 when the respective wear reducing feature(s) 606, 608 are viewed in section view.

FIG. 6B shows an alternative arrangement for the wear reducing features of a reticle contact according to FIG. 6A. In reticle contact 615 of FIG. 6B, while body 602 and reticle contact region 604 are provided, a plurality of wear reducing features 617 are provided on the reticle contact region 604, instead of first and second wear reducing features 606, 608. The wear reducing features can each be an elongate projection outward from the surface of reticle contact region 604. The wear reducing features 617 can have a generally rectangular or oblong cross-sectional shape. In an embodiment, the wear reducing features 617 are arranged radially extending outwards from a center of the reticle contact region.

### Aspects:

Aspect 1. An article comprising a reticle contact for a reticle pod, the reticle contact including:
a reticle contact body configured to be received in a cover of the reticle pod or a baseplate of the reticle pod; and
a reticle contact region at a distal end of the reticle contact body, wherein the reticle contact region includes a wear reduction feature.

Aspect 2. The article according to aspect 1, wherein the wear reduction feature includes one or more elongate arcing projections.

Aspect 3. The article according to aspect 2, wherein the one or more elongate arcing projections surround a reticle contact region.

Aspect 4. The article according to any of aspects 2-3, wherein the one or more elongate arcing projections include one or more rings, each of said one or more rings surrounding a center of the reticle contact region.

Aspect 5. The article according to any of aspects 2-4, wherein a maximum height of the reticle contact region is provided on at least one of the one or more arcing projections, and wherein transitions from side walls of the one or more arcing projections to a reticle contact surface of the one or more arcing projections are radiused over a distance of 0.3 millimeters (mm) or less.

Aspect 6. The article according to any of aspects 1-5, wherein the wear reduction feature includes at least one relief provided in the reticle contact region.

Aspect 7. The article according to aspect 6, wherein the relief has a depth of at least 0.1 millimeters (mm).

Aspect 8. The article according to any of aspects 6-7, wherein the at least one relief includes a ring-shaped trench.

Aspect 9. The article according to aspect 8, wherein the ring-shaped trench has an inner diameter in a range from 0.1 millimeters (mm) to 3.0 mm.

Aspect 10. The article according to any of aspects 8-9, wherein transitions from side walls of the ring-shaped trench to a reticle contact surface of the reticle contact region are radiused over a distance of 0.3 millimeters (mm) or less.

Aspect 11. The article according to any of aspects 1-10, wherein the wear reduction feature includes a first region of the reticle contact region where a thickness of the reticle contact is relatively less than a thickness of the reticle contact at a second region of the reticle contact surface.

Aspect 12. The article according to aspect 11, wherein the first region of the reticle contact overlaps with a center of the reticle contact region.

Aspect 13. The article according to any of aspects 1-12, wherein the wear reduction feature includes a plurality of projections from the reticle contact region, wherein at least one of the plurality of projections has an elongate cross-sectional shape.

Aspect 14. The article according to any of aspects 1-13, wherein the reticle contact surface has a radius R1, a transition between the side wall of the wear reducing feature to the reticle contact surface has a radius R2, and R2 is less than 80% of R1.

Aspect 15. The article according to any of aspects 1-12, further comprising a flexible mounting configured to allow the reticle contact to move relative the cover of the reticle pod or the baseplate of the reticle pod when the flexible mounting is deformed.

Aspect 16. A reticle pod, comprising a cover, a baseplate, and at least one of the article according to any of aspects 1-15.

Aspect 17. The reticle pod according to aspect 16, further comprising a pod dome and a pod door.

Aspect 18. A reticle pod, comprising a cover, a baseplate, and a plurality of the articles according to any of aspects 1-15.

Aspect 19. The reticle pod according to aspect 18, wherein some of the plurality of the articles are provided on the cover and some of the plurality of the articles are provided on the baseplate.

Aspect 20. The reticle pod according to any of aspects 18-19, further comprising a pod dome and a pod door.

Aspect 21. The reticle pod according to aspect 14, wherein the side wall of the wear reducing feature has a height of 0.2 mm or greater.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article comprising a reticle contact for a reticle pod, the reticle contact including:
a reticle contact body configured to be received in a cover of the reticle pod or a baseplate of the reticle pod; and
a reticle contact region at a distal end of the reticle contact body, wherein the reticle contact region includes a wear reduction feature.

2. The article of claim 1, wherein the wear reduction feature includes one or more elongate arcing projections.

3. The article of claim 2, wherein the one or more elongate arcing projections surround a reticle contact region.

4. The article of claim 2, wherein the one or more elongate arcing projections include one or more rings, each of said one or more rings surrounding a center of the reticle contact region.

5. The article of claim 2, wherein a maximum height of the reticle contact region is provided on at least one of the one or more arcing projections, and wherein transitions from side walls of the one or more arcing projections to a reticle contact surface of the one or more arcing projections are radiused over a distance of 0.3 millimeters (mm) or less.

6. The article of claim 1, wherein the wear reduction feature includes at least one relief provided in the reticle contact region.

7. The article of claim 6, wherein the relief has a depth of at least 0.1 millimeters (mm).

8. The article of claim 6, wherein the at least one relief includes a ring-shaped trench.

9. The article of claim 8, wherein the ring-shaped trench has an inner diameter in a range from 0.1 millimeters (mm) to 3.0 mm.

10. The article of claim 8, wherein transitions from side walls of the ring-shaped trench to a reticle contact surface of the reticle contact region are radiused over a distance of 0.3 millimeters (mm) or less.

11. The article of claim 1, wherein the wear reduction feature includes a first region of the reticle contact region where a thickness of the reticle contact is relatively less than a thickness of the reticle contact at a second region of the reticle contact surface.

12. The article of claim 11, wherein the first region of the reticle contact overlaps with a center of the reticle contact region.

13. The article of claim 1, wherein the wear reduction feature includes a plurality of projections from the reticle contact region, wherein at least one of the plurality of projections has an elongate cross-sectional shape.

14. The article of claim 1, wherein the reticle contact surface has a radius R1, a transition between the side wall of the wear reducing feature to the reticle contact surface has a radius R2, and R2 is less than 80% of R1.

15. The article of claim 14, wherein the side wall of the wear reducing feature has a height of 0.2 mm or greater.

16. The article of claim 1, further comprising a flexible mounting configured to allow the reticle contact to move relative the cover of the reticle pod or the baseplate of the reticle pod when the flexible mounting is deformed.

17. A reticle pod, comprising a cover, a baseplate, and at least one of the article according to claim 1.

18. The reticle pod of claim 17, further comprising a pod dome and a pod door.

19. A reticle pod, comprising a cover, a baseplate, and a plurality of the articles according to claim 1.

20. The reticle pod of claim 19, further comprising a pod dome and a pod door.
